(19) United States
(12) Patent Application Publication
(10) Pub. No.: US 2026/0322344 A1
(43) Pub. Date: Oct. 15, 2026

(54) RECONFIGURABLE MULTI-CORE INDUCTOR-CAPACITOR VOLTAGE-CONTROLLED OSCILLATOR

(71) Applicant: Marvell Asia Pte Ltd, Singapore (SG)

(72) Inventors: Junheng Zhu, San Diego, CA (US); Amrutha Sahasranaman Iyer, San Jose, CA (US); Shahram Mahdavi, Santa Clara, CA (US); Han-Yuan Tan, Santa Clara, CA (US); Cindra Widya Abidin, Irvine, CA (US); Qiwei Wang, Fremont, CA (US); Stanley Siu Kee Ho, Richmond (CA); Tomas Alexander Dusatko, North Vancouver (CA); Vivekananth Gurumoorthy, Fremont, CA (US)

(73) Assignee: Marvell Asia Pte Ltd, Singapore (SG)

(21) Appl. No.: 19/642,875

(22) Filed: Apr. 9, 2026

Related U.S. Application Data
(60) Provisional application No. 63/786,876, filed on Apr. 10, 2025.

(51) Int. Cl. H03H 7/01; H03H 1/00

(52) U.S. Cl. CPC H03H 7/0115; H03H 1/0007; H03H 7/0153; H03H 2007/0192

(57) ABSTRACT

As integrated circuit densities increase, electromagnetic (EM) coupling between closely-spaced inductor-capacitor (LC) voltage-controlled oscillators (VCOs) can degrade phase noise performance in multi-lane transceivers. To address this, a reconfigurable multi-core LC VCO architecture is proposed that mitigates EM coupling through a programmable interconnection topology. Two or more parallel LC cores are coupled via transmission-gate switches, enabling multiple operating modes: single-core (low-power), multi-core direct connection (victim immunity), and multi-core cross-coupling connection (aggressor suppression). Parallel coupling of LC cores can preserve inductor Q-factor while achieving significant EM field cancellation. The architecture supports per-lane independent configuration in multi-lane transceiver systems, enabling simultaneous optimization of power consumption, phase noise, and chip-level EM compatibility.

### PRIORITY APPLICATION

This patent application claims priority to and/or receives benefit from U.S. Provisional Application No. 63/786,876, titled “Cross Coupled Dual Core LC VCO”, filed on Apr. 10, 2025. The U.S. Provisional Application is hereby incorporated by reference in its entirety.

### BACKGROUND

Modern high-speed transceivers integrate multiple transmit (TX) and receive (RX) lanes in parallel to meet increasing bandwidth demands in optical and wireline communication systems. Each lane incorporates a phase-locked loop (PLL) with an inductor-capacitor (LC) voltage-controlled oscillator (VCO) as the timing reference.

### BRIEF DESCRIPTION OF THE DRAWINGS

Examples will be readily understood by the following detailed description in conjunction with the accompanying drawings. To facilitate this description, like reference numerals designate like structural elements. Examples are illustrated by way of example, and not by way of limitation, in the figures of the accompanying drawings.

FIG. 1 illustrates an example communication system, according to some examples of the disclosure.

FIG. 2 illustrates an example phase-locked loop, according to some examples of the disclosure.

FIG. 3A illustrates direct- or straight-coupling of inductors, according to some examples of the disclosure.

FIG. 3B illustrates cross-coupling of inductors, according to some examples of the disclosure.

FIG. 4 illustrates a reconfigurable multi-core LC VCO, according to some examples of the disclosure.

FIG. 5A illustrates an implementation of a switching circuit, according to some examples of the disclosure.

FIG. 5B illustrates an implementation of a switching circuit, according to some examples of the disclosure.

FIG. 5C illustrates an implementation of a switch as a transmission-gate switch, according to some examples of the disclosure.

FIG. 6 illustrates a transceiver having a plurality of reconfigurable multi-core LC VCOs, according to some examples of the disclosure.

FIG. 7 depicts a flow chart illustrating a method for reducing electromagnetic coupling associated with an inductor-capacitor voltage-controlled oscillator on an integrated circuit, according to some examples of the disclosure.

FIG. 8 depicts a flow chart illustrating a method for reducing electromagnetic coupling associated with an inductor-capacitor voltage-controlled oscillator on an integrated circuit, according to some examples of the disclosure.

### DETAILED DESCRIPTION

### Overview

Modern high-speed receivers, transmitters, and transceivers integrate many communication lanes in parallel to meet increasing bandwidth demands in optical and wireline communication systems. Each communication lane can include a PLL using a VCO as the timing reference, some operating in the 20-28 GHz range. As process nodes shrink and chip integration densities increase, the physical spacing between adjacent LC VCOs becomes increasingly constrained, making electromagnetic (EM) coupling between lanes a design challenge. EM coupling between VCOs operating at similar or identical frequencies can induce spurious tones and degrade phase noise, directly impacting link performance. Furthermore, chip top-level routing and seal rings introduce additional EM aggressors that compound the coupling problem.

Some approaches to mitigating EM coupling include increasing physical separation between sensitive blocks, employing EM-induced spur cancellation techniques, or adopting alternative oscillator architectures such as ring oscillators. However, physical separation is increasingly impractical as competitive pressures drive aggressive area scaling. EM spur cancellation is difficult to simulate accurately with existing tools, creating high production risk. Ring oscillators, while insensitive to EM coupling, exhibit a random jitter performance gap compared to LC oscillators and cannot meet stringent system specifications. While a figure-8 single inductor LC design may offer some EM radiation suppression through self-cancelling magnetic fields, the figure-8 single inductor LC design suffers from inherent limitations. For example, the series-connected inductor halves of the figure-8 single inductor design increases resistive losses and degrades quality factor (Q). Moreover, the figure-8 single inductor design is non-reconfigurable.

To address at least some of the challenges and limitations, a reconfigurable multi-core LC VCO architecture that employs programmable transmission-gate switches to interconnect two or more parallel LC cores can be implemented for high-density communication systems. The reconfigurable multi-core LC VCO can support reconfiguration between multiple operating modes or states without redesign or layout modification. The technical benefit is a hardware system that can be optimized, in some cases post-fabrication, for different EM environments and system requirements. The multi-core approach is scalable to using N cores in parallel.

The reconfigurable multi-core LC VCO is formed by interconnecting two or more (standard) LC VCO cores through a programmable switching network comprising transmission-gate switches disposed between the output nodes of adjacent cores. A transmission-gate (T-gate) switch can include complementary N-type metal-oxide-semiconductor (NMOS) and P-type metal-oxide-semiconductor (PMOS) transistor devices that selectively establish or couple, or break or decouple, a conductive path between a node of one core and a corresponding or complementary node of an adjacent core. The T-gate topology offers low and relatively constant on-resistance across the full signal swing, which can be beneficial for maintaining strong coupling between cores. In some examples, switch on-resistance may be minimized or reduced to avoid degrading coupling strength, while switch sizing may be constrained to limit parasitic capacitance loading on the LC tank. The parasitic capacitance appears at each connection point and can be absorbed into the VCO frequency tuning range design budget. Despite these constraints, T-gate switches can achieve sufficiently low on-resistance without limiting performance, enabling the reconfigurable architecture without compromise to baseline single-core specifications.

By programming the switch states, the switching network can reconfigure the multi-core LC VCO among two or more operating modes. One operating mode can correspond to all switches being open for single-core (low-power) operation. Another operating mode can correspond to the switches being closed for direct connections (P-to-P, N-to-N) for dual-core victim immunity. Another operating mode can correspond to the switches being closed in cross-coupling connection (P-to-N, N-to-P) for dual-core aggressor suppression. The switch configuration determines whether the cores are coupled in straight or direct, or cross topology.

In straight-coupled mode, the differential nature of each LC core causes the current to circulate in opposite rotational directions in the two inductors such that the cores oscillate in anti-phase, generating electromagnetic flux in opposing directions in each core. In this mode, any externally induced interference produces equal and opposing responses at the cross-coupled output terminals. The interference cancels within the dual-core structure and reduces the VCO's susceptibility as an EM victim.

In cross-coupled mode, the polarity-swapping interconnection causes the current to circulate in the same rotational direction in both inductors such that the cores oscillate in-phase, generating electromagnetic flux in the same direction in each core. In this mode, the radiated fields cancel in the far field, reducing the VCO's role as an EM aggressor to other components on the integrated circuit die.

In some examples, both configurations achieve equivalent phase noise or jitter performance, meaning the reconfiguration provides EM optimization at zero cost to timing jitter. The multi-mode capability addresses both aggressor and victim scenarios within a single design. Additionally, this programmable switching network enables independent per-lane optimization of one or more of power consumption, phase noise, and electromagnetic coupling behavior across multi-lane transceiver systems, without requiring layout or design modifications post-fabrication.

Unlike the series-connected halves of a single figure-8 inductor topology, the reconfigurable multi-core LC VCO architecture employs two or more high-Q inductors connected in parallel through the switch network. Series connection inherently increases the resistive path length, degrading inductor Q-factor and consequently worsening phase noise. Parallel coupling maintains the individual Q of each inductor while providing mutual injection locking benefits. The effective inductance seen by the oscillator core is the parallel combination, and the switch on-resistance can be designed to negligibly impact coupling strength. Advantageously, EM suppression is achieved through current flow topology rather than inductor geometry modification and decouples EM mitigation from resonator performance.

When the programmable switches are opened, the multiple cores may operate independently, and a subset of cores can be powered down entirely. This single-core or reduced-core mode provides a low-power operating state for scenarios where EM coupling is not a concern or where system bandwidth requirements are reduced. The ability to trade performance for power consumption within the same silicon footprint can enable adaptive power management strategies. For example, in idle or low-traffic states, the transceiver can operate in single-core mode, reducing PLL power consumption. This multi-mode architecture (e.g., supporting single-core, dual-core direct, and dual-core cross modes) provides a two-dimensional optimization space: the number of active cores for power management and coupling topology for EM management.

In dual-core mode, the two LC cores operate at the same or nearly identical free-running frequencies and are mutually coupled through the programmable switching network, enabling mutual injection locking within the locking bandwidth determined by the coupling strength. Mutual injection between synchronized oscillator cores can suppress free-running phase noise contributions, providing a performance incentive for dual-core operation beyond EM mitigation alone. The coupling strength is governed by the switch on-resistance, which, when reduced or minimized through appropriate transistor sizing, can widen the injection locking range, while managing the associated parasitic capacitance loading on the LC tank. Jitter performance and phase noise enhancement can be, in some examples, equivalent across both direct and cross-coupling configurations.

In multi-lane transceiver systems, a TX/RX lane can incorporate its own instance of the reconfigurable multi-core LC VCO with independent switch control. This design enables per-lane optimization of the operating mode based on one or more factors, including the local EM environment, power budget, and performance requirements. For example, in a four-lane transceiver with a stacked layout, alternating lanes could be configured in cross-coupling and direct modes to achieve optimal chip-level EM cancellation. Lanes located near other sensitive circuits (e.g., low-noise amplifiers, transmitter inductors) can prioritize aggressor suppression (cross-coupled mode), while lanes subjected to strong external EM sources can prioritize victim immunity (straight-coupled mode). This spatial diversity in configuration represents a system-level degree of freedom unavailable in fixed-topology designs.

While some examples described herein employ two cores, the architecture generalizes to N cores in parallel, each interconnected through a programmable switch matrix. Increasing the number of cores provides additional phase noise reduction through enhanced injection locking and offers finer granularity in power-performance trade-offs (e.g., activating one, two, or three cores depending on operating conditions). The EM field cancellation principles extend to multi-core configurations through appropriate switch programming.

The reconfigurable multi-core LC VCO is application-agnostic and applicable to any PLL-based transceiver system. The EM coupling problem is common to optical (coherent and intensity-modulated), copper wireline (Ethernet, SerDes), and communication physical layer (PHY) applications employing LC VCOs operating at frequencies where EM coupling is significant and area constraints preclude simple physical separation. The reconfigurable multi-core LC VCO is also inductor-topology-agnostic, and an individual inductor core of the multi-core LC VCO can implement a standard circular design, an octagonal design, or a figure-8 inductor design.

The programmable switch network of the reconfigurable multi-core LC VCO enables post-silicon optimization of EM behavior. During chip bring-up and characterization, different switch configurations can be evaluated to empirically determine the optimal setting for each lane based on measured phase noise, spur content, and EM coupling to adjacent circuits. This reconfigurability can be particularly valuable given the difficulty of accurately simulating EM coupling in the lab. The reconfigurability provides a hardware-based mitigation knob that can compensate for simulation inaccuracies and post-fabrication variations. In some examples, the switch configuration can be programmed via registers, enabling field updates or adaptive algorithms that adjust coupling topology based on operating conditions or adjacent channel activity.

At the chip-level, the ability to independently configure multiple VCO instances enables advantageous EM compatibility strategies. For example, VCOs can be configured to minimize radiation toward known victim circuits (e.g., low-noise receivers) or to maximize immunity when positioned near known aggressors (e.g., power amplifiers, chip routing). The two-dimensional configurability involving a number of active cores and coupling topology provides orthogonal optimization axes for power and EM performance. This chip-level perspective is critical because EM coupling is not solely a VCO-to-VCO phenomenon. Top-level routing, seal rings, and other high-current circuits also contribute to the EM environment. The reconfigurable VCO architecture thus serves as a flexible building block in a holistic EM management strategy, reducing the burden on chip floor planning and enabling more aggressive area scaling.

### Example Communication System Implementing Reconfigurable Multi-Core LC VCOs in the PLLs

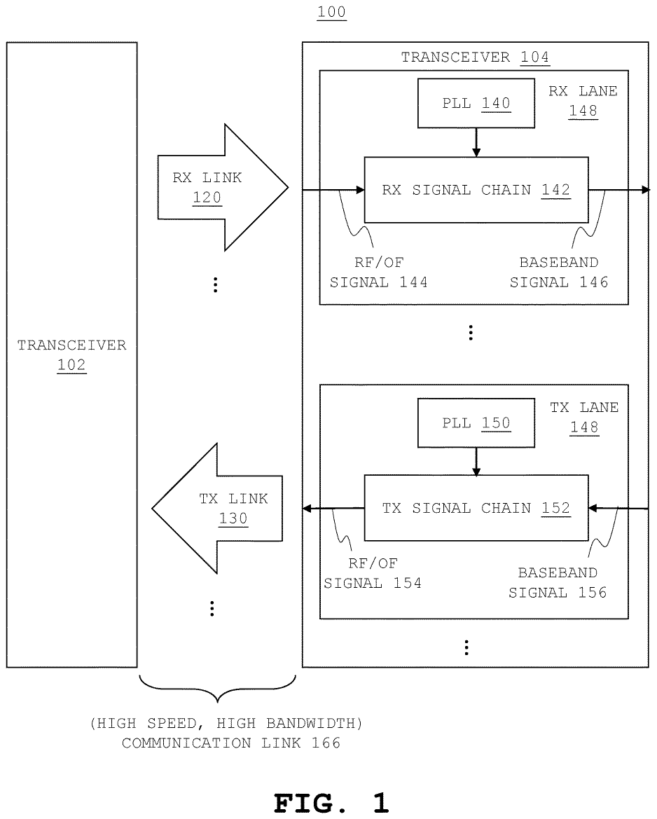

FIG. 1 illustrates an example communication system 100, according to some examples of the disclosure. Communication system 100 comprises one or more of: transceiver 102, transceiver 104, and communication link 166. Communication link 166 couples transceiver 102 to transceiver 104 and may represent a high-speed, high-bandwidth communication link, such as an optical fiber, a copper interconnect, or a wireline channel, e.g., operating in the 20-28 GHz range. In some examples, communication system 100 may represent a multi-lane optical or wireline communication system in which a plurality of receive (RX) lanes and transmit (TX) lanes operate in parallel to achieve the aggregate bandwidth demanded by modern data center and networking applications.

Transceiver 104 comprises one or more of: an RX lane 148, a TX lane 148, a PLL 140, an RX signal chain 142, a PLL 150, and a TX signal chain 152. As used herein, a “lane” refers to an independently operable signal processing path paired with a dedicated clock generation circuit. RX lane 148 and TX lane 148 each represent an individually configurable communication lane within transceiver 104. Each lane can comprise a respective signal processing path and a respective phase-locked loop coupled to the signal processing path. The vertical ellipsis between RX lane 148 and TX lane 148 indicates that transceiver 104 may comprise a plurality of additional RX lanes and TX lanes, supporting scalable multi-lane operation. In some examples, transceiver 104 may be implemented as an integrated circuit on a single semiconductor die, where the plurality of lanes are disposed in close physical proximity, giving rise to electromagnetic (EM) coupling between adjacent phase-locked loops.

RX signal chain 142 and TX signal chain 152 may each represent a signal processing path within a respective communication lane. RX link 120 and TX link 130 may each represent a unidirectional signal path between transceiver 102 and transceiver 104 over communication link 166. RX link 120 carries an incoming signal from transceiver 102 to RX signal chain 142, and TX link 130 carries an outgoing signal from TX signal chain 152 to transceiver 102. RX signal chain 142 receives a radio frequency (RF) or optical frequency (OF) signal 144 from RX link 120 and processes the received signal to produce baseband signal 146 for further digital processing. TX signal chain 152 receives baseband signal 156 and processes the signal to produce RF/OF signal 154 for transmission over TX link 130 to transceiver 102. RX signal chain 142 and TX signal chain 152 can each include one or more of: analog front-end circuitry, mixers, filters, amplifiers, analog-to-digital converters, digital-to-analog converters, and equalizers. In some examples, a plurality of RX links 120 and TX links 130 may operate simultaneously across the plurality of RX lanes and TX lanes of transceiver 104.

In some examples, RX signal chain 142 and TX signal chain 152 are clocked by PLL 140 and PLL 150, respectively. PLL 140 and PLL 150 may each provide a clock reference signal to RX signal chain 142 and TX signal chain 152, respectively. The phase noise and jitter performance of PLL 140 and PLL 150 can impact the signal integrity of signals being processed by RX signal chain 142 and TX signal chain 152. In particular, the close physical spacing of the corresponding PLL 140 and PLL 150 instances on the integrated circuit die introduces EM coupling between adjacent lanes.

To address this issue, PLL 140 and PLL 150 may individually or each comprise a reconfigurable multi-core LC VCO having a plurality of inductor-capacitor cores and a switching circuit coupled to terminals of the plurality of inductor-capacitor cores. The switching circuit is controllable by one or more control signals to operate in a selected one of multiple states. The multiple states can include one or more of: a low-power state corresponding to the plurality of inductor-capacitor cores being decoupled from each other, a straight-coupled state corresponding to the plurality of inductor-capacitor cores being straight-coupled with each other for victim immunity, and a cross-coupled state corresponding to the plurality of inductor-capacitor cores being cross-coupled with each other for aggressor suppression.

In some examples, PLL 140 and PLL 150 may be independently configured to operate their respective reconfigurable multi-core LC VCOs in different states, enabling per-lane optimization of one or more of power consumption, phase noise, and chip-level electromagnetic compatibility. Specifically, the reconfigurable multi-core LC VCO within each of PLL 140 and PLL 150 addresses this EM coupling by enabling independent per-lane selection of the operating state.

### Example PLL

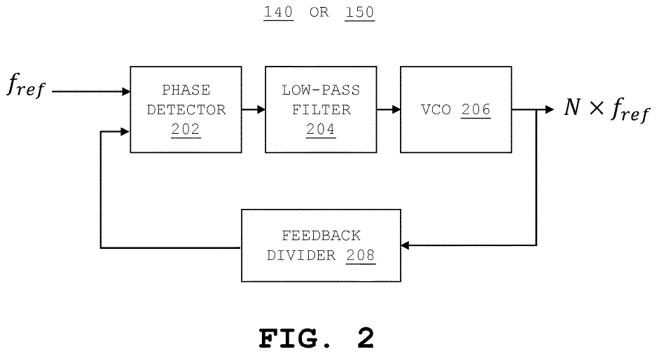

FIG. 2 illustrates an example phase-locked loop, such as PLL 140 or PLL 150, according to some examples of the disclosure. PLL 140 or 150 comprises one or more of: phase detector 202, low-pass filter 204, VCO 206, and feedback divider 208. Phase detector 202 receives a reference frequency signal f_{ref} and a divided feedback signal from feedback divider 208 and generates an error signal proportional to the phase difference between the two inputs. Low-pass filter 204 receives the error signal from phase detector 202 and filters out high-frequency noise components to produce a smooth control voltage, which is applied to VCO 206. VCO 206 generates an output clock signal at a frequency of N×f_{ref}. N represents the division ratio programmed into feedback divider 208. Feedback divider 208 receives the output clock signal from VCO 206 and divides the output frequency by N before feeding the divided signal back to phase detector 202, closing the feedback loop. When PLL 140 or 150 is in a locked state, the divided output frequency matches the reference frequency f_{ref}, such that the output of VCO 206 is a stable, low-jitter clock signal at the desired multiplication of f_{ref}. In some examples, PLL 140 or 150 may be used in high-speed communication systems to generate a precise clock reference for signal processing chains, where the phase noise and jitter performance of VCO 206 directly determine the quality of the generated clock signal and the overall link performance of the communication system.

### Straight-Coupling Versus Cross-Coupling of Inductors

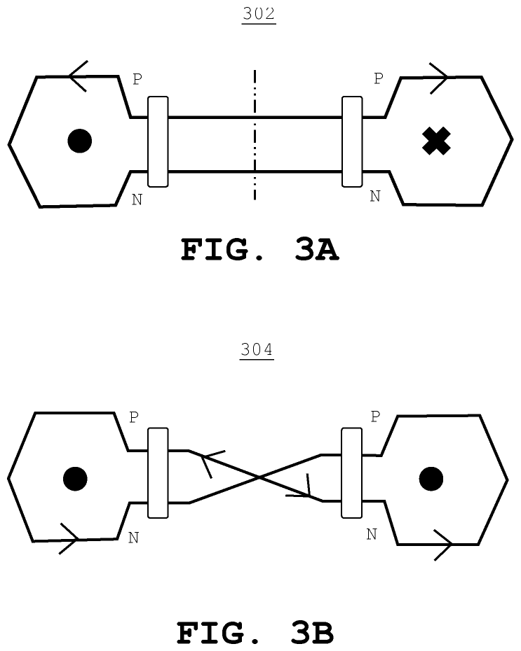

FIG. 3A illustrates straight-coupled state 302 corresponding to direct- or straight-coupling of inductors, according to some examples of the disclosure. In straight-coupled state 302, a switching circuit interconnects two LC VCO cores in a direct, parallel topology, where a positive terminal (P) of a first LC core is electrically coupled to a positive terminal (P) of a second LC core, and a negative terminal (N) of the first LC core is electrically coupled to a negative terminal (N) of the second LC core through respective switch elements. Although the straight-coupled topology connects P-to-P and N-to-N, the two LC cores are mirror images of each other in layout, meaning there is one core on the left, and one core on the right of the switching circuit. When the straight-coupled interconnect ties P-to-P and N-to-N, the P-high/N-low polarity condition is the same in both cores at any given instant. However, because the two inductors are mirror images, the same P-high/N-low condition drives current in a counter-clockwise direction in one inductor and a clockwise direction in the other. By the right-hand rule, counter-clockwise current produces flux emerging out of the page, while clockwise current produces flux entering into the page. The two cores therefore oscillate in anti-phase, with currents circulating in opposite rotational directions, producing the opposing dot-cross flux pattern shown in FIG. 3A. The dot symbol within the first LC core and the cross symbol within the second LC core represent opposing electromagnetic field directions. The field is emerging out of the page in the first LC core and entering into the page in the second LC core. Although straight-coupled state 302 connects P-to-P and N-to-N, the differential oscillation of each LC core means that the current circulates in opposite rotational directions in the two inductors, generating magnetic flux in opposite directions. As a consequence, any external electromagnetic field coupling into the dual-core structure induces voltages that appear as a common-mode signal across the two cores, subtracting at the differential output terminals and cancelling within the structure. Straight-coupled state 302 therefore configures the reconfigurable multi-core LC VCO to minimize its susceptibility as an EM victim, maximizing immunity to externally coupled electromagnetic interference originating from nearby aggressors, such as adjacent VCO instances, chip top-level routing, or seal ring structures.

FIG. 3B illustrates cross-coupled state 304 corresponding to cross-coupling of inductors, according to some examples of the disclosure. In cross-coupled state 304, a switching circuit interconnects two LC VCO cores in a criss-cross topology, where a positive terminal (P) of a first LC core is electrically coupled to a negative terminal (N) of a second LC core, and a negative terminal (N) of the first LC core is electrically coupled to a positive terminal (P) of the second LC core, as depicted by the crossing interconnections between the switch elements at the center of the figure. Although the criss-cross topology inverts the interconnect polarity, this inversion cancels the geometric flip arising from the mirror-image layout of the two LC cores, such that both inductors carry current in the same rotational direction, resulting in in-phase oscillation and co-directional flux. The two LC cores are mirror images of each other in layout. One core is on the left, and the other core is on the right of the switching circuit. In the criss-cross topology, when P of a first core swings high, it pulls the N of the second core high, effectively inverting the polarity presented to the second core relative to the first core. This polarity inversion cancels the geometric flip that the mirror-image layout would otherwise introduce. As a result, both inductors carry current in the same rotational direction. By the right-hand rule, both inductors therefore generate flux in the same direction, producing the co-directional dot-dot flux pattern shown in FIG. 3B, and the two cores oscillate in-phase. The dot symbols within both the first LC core and the second LC core represent electromagnetic fields emerging out of the page in both cores, indicating that the two LC cores generate magnetic flux in the same direction. Although cross-coupled state 304 connects P-to-N and N-to-P, the polarity-swapping interconnection causes the current to circulate in the same rotational direction in both inductors. The resulting co-directional flux fields add constructively within the dual-core structure but cancel each other in the far field because the two inductors are physically separated and their radiated fields interfere destructively at a distance. Cross-coupled state 304 therefore configures the reconfigurable multi-core LC VCO to minimize its role as an EM aggressor, reducing electromagnetic radiation emitted toward other sensitive circuits on the same integrated circuit die, such as adjacent phase-locked loops, low-noise amplifiers, or transmitter inductors.

Taken together, FIG. 3A and FIG. 3B illustrate two complementary and independently selectable EM suppression modes of the reconfigurable multi-core LC VCO. Straight-coupled state 302 can be selected for victim immunity. Cross-coupled state 304 can be selected for aggressor suppression. In some examples, the selection between states is programmable on a per-lane basis without degradation to phase noise or jitter performance, as both states can maintain equivalent oscillator performance through parallel inductor coupling.

The following table summarizes characteristics of the modes of the reconfigurable multi-core LC VCO:

| | State | | | |
|---|---|---|---|---|
| Mode | Topology | Oscillation | Flux | EM function |
| Straight-coupled | P-P, N-N | Anti-phase | Opposing | Victim |
| (FIG. 3A) | | | (dot-cross) | immunity |
| Cross-coupled | P-N, N-P | In-phase | Same | Aggressor |
| (FIG. 3B) | | | (dot-dot) | suppression |

### Example Reconfigurable Multi-Core LC VCO

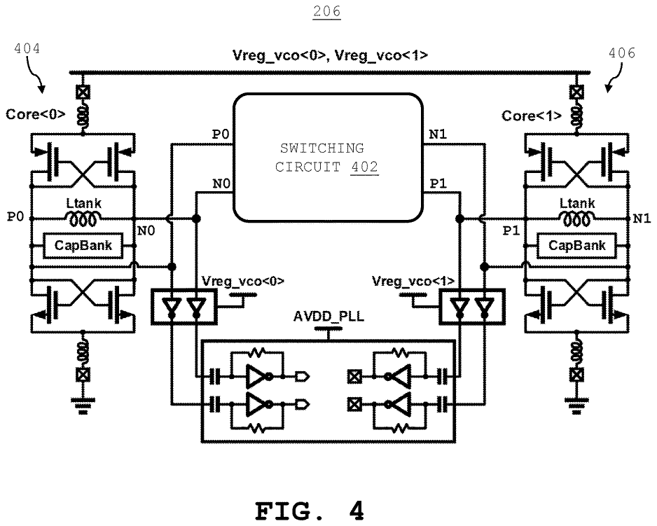

FIG. 4 illustrates reconfigurable multi-core LC VCO 206, according to some examples of the disclosure. Reconfigurable multi-core LC VCO 206 comprises two LC VCO cores, e.g., Core<0> 404 and Core<1> 406, illustrated symmetrically on the left and right sides of the figure, and switching circuit 402 illustrated and disposed between Core<0> 404 and Core<1> 406.

Core<0> 404 exposes a positive terminal P0 and a negative terminal N0, and Core<1> 406 exposes a positive terminal P1 and a negative terminal N1. Terminals P0, N0, P1, and N1 are each coupled to a respective port of switching circuit 402. Switching circuit 402 is controllable by one or more control signals to selectively interconnect terminals P0, N0, P1, and N1 in a selected one of multiple states, including two or more of a straight-coupled state, a cross-coupled state, and a decoupled state.

Core<0> 404 and Core<1> 406 each comprise one or more of: an inductor Ltank, a capacitor bank CapBank, and other circuitry. Ltank provides the inductive element of the LC tank resonator and determines, together with CapBank (which provides the capacitive element of the LC tank resonator), the resonant frequency of the respective LC VCO core. CapBank is a programmable capacitor bank that enables tuning of the oscillation frequency across a desired frequency range, for example in the 20-28 GHz range, by selectively switching capacitive elements in or out of the LC tank. A supply voltage Vreg_vco<0> is provided to Core<0> 404 and a supply voltage Vreg_vco<1> is provided to Core<1> 406. Vreg_vco<0> and Vreg_vco<1> can be independently regulatable voltage rails distributed across the top of the figure, enabling independent power control of each LC VCO core. In some examples, each of Core<0> 404 and Core<1> 406 receives a respective regulated supply voltage Vreg_vco<0> or Vreg_vco<1>, which controls the operating condition of the active transistor devices and enables independent per-core power management, including the ability to power down one core entirely in the decoupled state.

In some examples, switching circuit 402 comprises a plurality of transmission-gate switches, each comprising a complementary NMOS and PMOS device pair, that selectively establish or break conductive paths between terminals P0, N0, P1, and N1 of Core<0> 404 and Core<1> 406.

In the straight-coupled state, switching circuit 402 can electrically couple P0 to P1 and N0 to N1, causing both cores to oscillate in anti-phase and generating electromagnetic flux in opposing directions in each core for victim immunity.

In the cross-coupled state, switching circuit 402 electrically couples P0 to N1 and N0 to P1 through the crossing interconnections visible at the center of switching circuit 402, imposing a polarity inversion on Core<1> 406 relative to Core<0> 404, causing both cores to oscillate in-phase and generating electromagnetic flux in the same direction in each core for aggressor suppression.

In the decoupled state, all switches within switching circuit 402 are open, electrically isolating Core<0> 404 from Core<1> 406 and enabling single-core operation for power saving. One of Core<0> 404 or Core<1> 406 may be powered down by disabling the respective Vreg_vco<0> or Vreg_vco<1> supply rail.

In some examples, control signals to switching circuit 402 may be generated by a controller based on one or more of a power mode of the communication system, a proximity of the communication lane to an adjacent communication lane, or a proximity of the communication lane to other electrical components of or near the integrated circuit, such as low-noise amplifiers or transmitter inductors.

In some examples, reconfigurable multi-core LC VCO 206 may be instantiated once per communication lane within a multi-lane transceiver, where each instance of reconfigurable multi-core LC VCO 206 is independently configurable via its own switching circuit 402 and control signals. The independent supply rails Vreg_vco<0> and Vreg_vco<1> enable per-core power management within each instance, and the independently controllable switching circuit 402 enables per-lane selection of two or more of the straight-coupled state, cross-coupled state, or decoupled operating state. In some examples, at least two instances of reconfigurable multi-core LC VCO 206 within the same integrated circuit may be configured to operate in different states simultaneously, enabling spatial diversity in electromagnetic coupling management across the chip and optimizing the aggregate electromagnetic compatibility of the multi-lane transceiver system.

### Examples of Switching Circuit

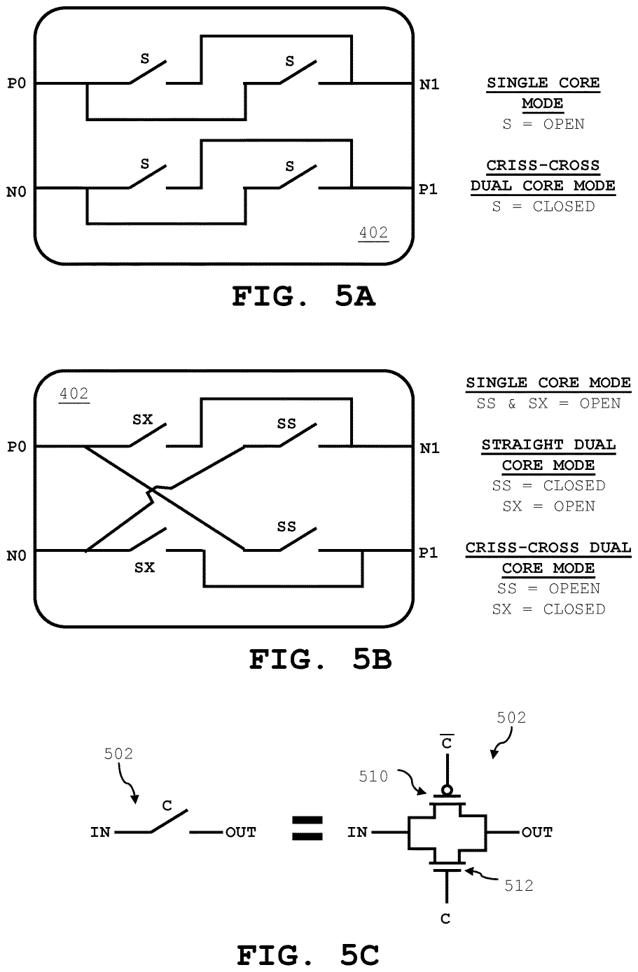

FIG. 5A illustrates an implementation of switching circuit 402, according to some examples of the disclosure. Switching circuit 402 can support single-core mode and criss-cross dual-core mode. Switching circuit 402 comprises a plurality of switches S disposed between positive terminal P0 and negative terminal N0 of a first LC core and positive terminal P1 and negative terminal N1 of a second LC core.

In single-core mode, all switches S are open, electrically isolating the terminals of the first LC core from the terminals of the second LC core, such that the two LC cores operate independently and one core may be powered down for power saving.

In criss-cross dual-core mode, all switches S are closed, electrically coupling P0 to N1 and N0 to P1 through the interconnections in switching circuit 402, imposing a polarity inversion on the second LC core relative to the first LC core, causing both cores to oscillate in-phase, and generating electromagnetic flux in the same direction in each core for aggressor suppression.

Switching circuit 402 in FIG. 5A can provide two-state reconfigurability between single-core operation and criss-cross dual-core operation. A set of switches S controls the transition between the two states by opening or closing all switches simultaneously.

While FIG. 5A illustrates a switching circuit 402 that supports single-core mode and criss-cross dual-core mode, an alternative embodiment of switching circuit 402 may be implemented to support single-core mode and straight dual-core mode. In such an alternative embodiment, the interconnections of switching circuit 402 depicted in FIG. 5A are replaced with straight interconnections, where closing all switches S electrically couples P0 to P1 and N0 to N1 rather than P0 to N1 and N0 to P1. In single-core mode, all switches S remain open, electrically isolating the first LC core from the second LC core in the same manner as described with respect to FIG. 5A. In straight dual-core mode, all switches S are closed, causing both cores to oscillate in anti-phase and generating electromagnetic flux in opposing directions in each core for victim immunity. This alternative embodiment may be selected in implementations where single-core low-power operation and straight dual-core victim immunity are prioritized.

FIG. 5B illustrates an implementation of switching circuit 402, according to some examples of the disclosure. Switching circuit 402 can support single-core mode, straight dual-core mode, and criss-cross dual-core mode. Switching circuit 402 comprises two sets of switches, e.g., a set of straight switches SS and a set of criss-cross switches SX, disposed between positive terminal P0 and negative terminal N0 of a first LC core and positive terminal P1 and negative terminal N1 of a second LC core.

In single-core mode, both SS and SX are open, electrically isolating the terminals of the first LC core from the terminals of the second LC core, enabling single-core low-power operation.

In straight dual-core mode, SS is closed and SX is open, electrically coupling P0 to P1 and N0 to N1 through the interconnections, causing both cores to oscillate in anti-phase and generating electromagnetic flux in opposing directions in each core for victim immunity.

In criss-cross dual-core mode, SS is open and SX is closed, electrically coupling P0 to N1 and N0 to P1 through the crossing interconnections, imposing a polarity inversion on the second LC core relative to the first LC core, causing both cores to oscillate in-phase, and generating electromagnetic flux in the same direction in each core for aggressor suppression.

Switching circuit 402 in FIG. 5B can provide three-state reconfigurability, e.g., single-core, straight dual-core, and criss-cross dual-core modes. Straight switches SS and criss-cross switches SX can be independently controllable and mutually exclusive, such that closing SS and opening SX selects straight dual-core mode, opening SS and closing SX selects criss-cross dual-core mode, and opening both SS and SX selects single-core mode.

FIG. 5C illustrates an implementation of switch 502 as a transmission-gate switch, according to some examples of the disclosure. Switch 502 can be used to implement a switch in switching circuit 402 as illustrated in FIGS. 4 and 5A-5B.

As shown on the left side of FIG. 5C, switch 502 is represented schematically as a single-pole single-throw switch controlled by control signal C to couple or decouple an input terminal IN and an output terminal OUT.

As shown on the right side of FIG. 5C, switch 502 is implemented as a transmission-gate comprising a PMOS transistor 510 and an NMOS transistor 512 connected in parallel between an input terminal IN and an output terminal OUT. PMOS transistor 510 is controlled by a complementary control signal C at its gate, and NMOS transistor 512 is controlled by control signal C at its gate, where C is the logical complement of C. When control signal C is asserted, NMOS transistor 512 and PMOS transistor 510 are both on simultaneously, providing a low-resistance conductive path between IN and OUT. When control signal C is de-asserted, both NMOS transistor 512 and PMOS transistor 510 are off, presenting a high-impedance open circuit between IN and OUT. The complementary NMOS-PMOS parallel topology of the transmission-gate provides a relatively constant and low on-resistance across the full signal voltage swing at the LC core terminals, which is beneficial for maintaining sufficient coupling strength between the first and second LC cores without degrading the quality factor of Ltank or introducing excessive parasitic capacitance loading at terminals P0, N0, P1, and N1 of switching circuit 402 as illustrated in FIGS. 4 and 5A-5B.

### Example Transceiver Having Independently Controllable Instances of the Reconfigurable Multi-Core LC VCOs

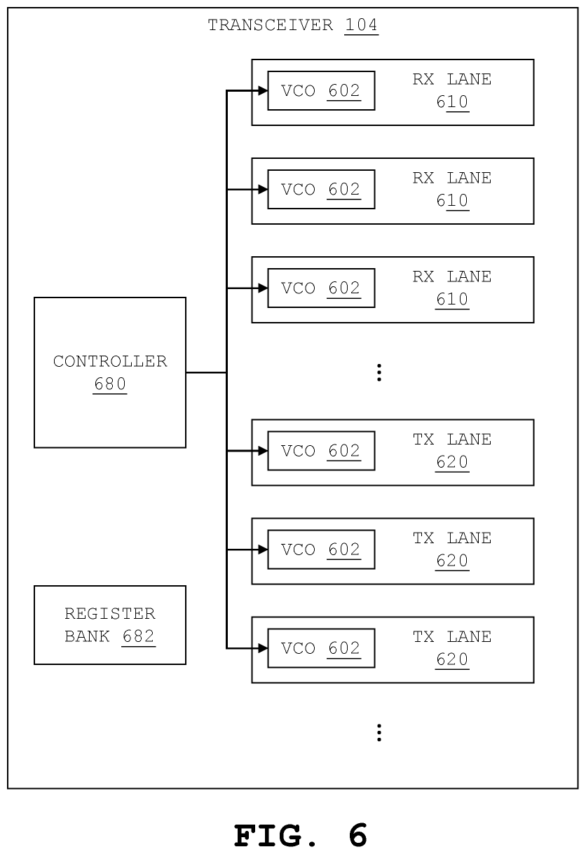

FIG. 6 illustrates transceiver 104 having a plurality of instances of reconfigurable multi-core LC VCO 602, according to some examples of the disclosure. Transceiver 104 can include a plurality of independently configurable communication lanes and controller 680. The communication lanes of transceiver 104 can include two or more of: one or more RX lanes 610 and one or more TX lanes 620. Transceiver 104 may comprise any number of RX lanes 610 and/or any number of TX lanes 620. The instances of reconfigurable multi-core LC VCO 602 can be provided for a plurality of (e.g., at least a subset of) the communication lanes, such as the one or more RX lanes 610 and one or more TX lanes 620. Transceiver 104 can include controller 680. Transceiver 104 supports scalable multi-lane operation with per-lane independent VCO configuration.

As illustrated, each RX lane 610 and each TX lane 620 may be paired with a dedicated reconfigurable multi-core LC VCO 602, where each VCO 602 comprises a switching circuit controllable to operate in a selected one of multiple states, including a single-core low-power state, a straight dual-core state for victim immunity, and a criss-cross dual-core state for aggressor suppression. In some examples, a reconfigurable multi-core LC VCO 602 may be shared with multiple communication lanes.

Controller 680 is coupled to one or more instances (e.g., at least a subset of instances) of VCO 602 for RX lanes 610 and TX lanes 620. For a given instance of VCO 602, controller 680 may output one or more control signals, e.g., independently from other instances of VCO 602, to select the operating state of the switching circuit in the given instance of VCO 602.

Controller 680 can provide a centralized point of control for one or more VCO 602 instances within transceiver 104, enabling a wide range of configuration possibilities across the plurality of RX lanes 610 and TX lanes 620.

In some examples, controller 680 may configure all VCO 602 instances to operate in the same state simultaneously. For example, controller 680 can configure all VCO 602 instances to criss-cross dual-core mode when all lanes are active and aggressor suppression is the primary concern across the entire chip.

In some examples, controller 680 may configure each VCO 602 instance independently in a different state. For example, controller 680 can configure VCO 602 of a first RX lane 610 to criss-cross dual-core mode for aggressor suppression, VCO 602 of a second RX lane 610 to straight dual-core mode for victim immunity, and VCO 602 of a third RX lane 610 to single-core mode for power saving, simultaneously.

In some examples, controller 680 may configure VCO 602 instances of RX lanes 610 differently from VCO 602 instances of TX lanes 620, reflecting the different EM environments and performance requirements of receive and transmit signal paths within transceiver 104.

In some examples, controller 680 may select the operating state of each VCO 602 based on a power mode of transceiver 104 or the communication system. For example, in a low-power mode, controller 680 may configure one or more VCO 602 instances to single-core mode, powering down one LC core within each selected VCO 602 to reduce overall power consumption while maintaining operation of the remaining active lanes. In a high-performance mode, controller 680 may configure all VCO 602 instances to either straight dual-core mode or criss-cross dual-core mode to maximize phase noise performance through mutual injection locking between the two LC cores of each VCO 602.

In some examples, controller 680 may configure individual VCO 602 instances to transition, over time, between operating states during operation of transceiver 104, adapting to changing power budgets, traffic loads, or electromagnetic environments without requiring reconfiguration of the integrated circuit.

In some examples, controller 680 may select the operating state of each VCO 602 based on the physical proximity of each RX lane 610 or TX lane 620 to other communication lanes or to other electrical components of or near transceiver 104, such as low-noise amplifiers, power amplifiers, transmitter inductors, chip top-level routing, or seal ring structures. For example, controller 680 may configure VCO 602 of an RX lane 610 or TX lane 620 disposed adjacent to a low-noise amplifier or other sensitive circuit to criss-cross dual-core mode to suppress electromagnetic radiation emitted toward the sensitive circuit. Controller 680 may configure VCO 602 of an RX lane 610 or TX lane 620 disposed adjacent to a strong EM aggressor, such as a transmitter inductor or high-current routing, to straight dual-core mode to maximize immunity to externally coupled electromagnetic interference.

In some examples, controller 680 may alternate the operating states of adjacent VCO 602 instances across the plurality of RX lanes 610 and TX lanes 620. For example, controller 680 can configure alternating lanes in criss-cross dual-core mode and straight dual-core mode to achieve optimal aggregate electromagnetic compatibility across transceiver 104 as a whole, exploiting the spatial diversity in VCO configuration as a system-level electromagnetic management strategy.

In some examples, the operating state of each VCO 602 selected by controller 680 may be stored in lane configuration register bank 682. Each register entry may store a respective configuration value corresponding to a selected one of the multiple states for a respective RX lane 610 or TX lane 620. The lane configuration register bank can enable persistent storage of per-lane VCO configuration values that survive power cycling or lane reset events. In some examples, lane configuration register bank 682 can support runtime reprogramming of individual lane configurations without disturbing the operating states of other lanes within transceiver 104. In some examples, the configuration values stored in lane configuration register bank 682 may be initialized at power-on based on a predetermined floorplan-aware electromagnetic compatibility analysis of transceiver 104. In some examples, the configuration values stored in lane configuration register bank 682 may be updated during operation based on measured phase noise, jitter, or spur levels. In some examples, the configuration values stored in lane configuration register bank 682 may be programmed externally via controller 680 and a system monitor to adapt to changing system-level electromagnetic conditions and observed signal conditions.

Example Methods for Reducing Electromagnetic Coupling Associated with an Inductor-Capacitor Voltage-Controlled Oscillator on an Integrated Circuit

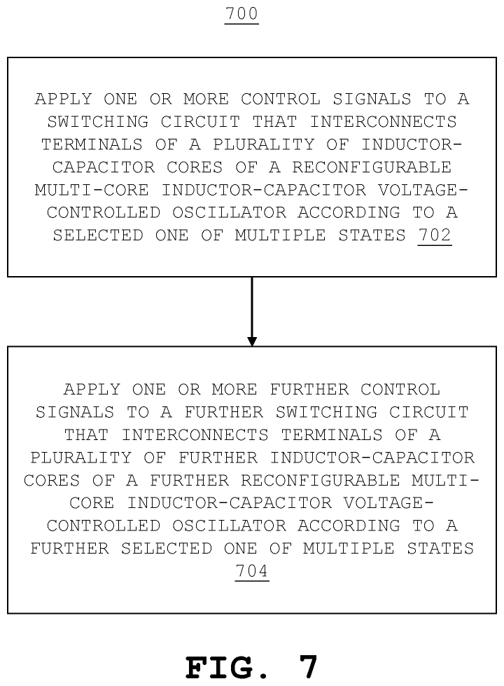

FIG. 7 depicts a flow chart illustrating method 700 for reducing electromagnetic coupling associated with an inductor-capacitor voltage-controlled oscillator on an integrated circuit, according to some examples of the disclosure. Method 700 can be implemented by one or more components as illustrated in FIGS. 1-6.

In 702, one or more control signals are applied to a switching circuit that interconnects terminals of a plurality of inductor-capacitor cores of a reconfigurable multi-core inductor-capacitor voltage-controlled oscillator according to a selected one of multiple states.

In 704, one or more further control signals are applied to a further switching circuit that interconnects terminals of a plurality of further inductor-capacitor cores of a further reconfigurable multi-core inductor-capacitor voltage-controlled oscillator according to a further selected one of multiple states.

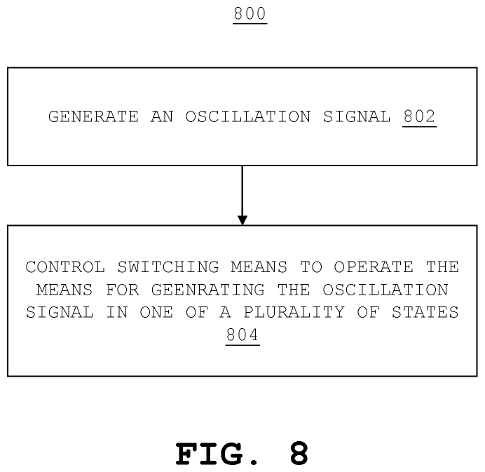

FIG. 8 depicts a flow chart illustrating method 800 for reducing electromagnetic coupling associated with an inductor-capacitor voltage-controlled oscillator on an integrated circuit, according to some examples of the disclosure. Method 800 can be implemented by one or more components as illustrated in FIGS. 1-6.

In 802, an oscillation signal is generated by oscillating means, where the oscillation means include inductive-capacitive means, further inductive-capacitive means, and switching means for interconnecting the inductive-capacitive means and the further inductive-capacitive means.

In 804, the switching means is controlled to operate the oscillating means in one of a plurality of states.

### Select Examples

Example 1 provides a reconfigurable multi-core inductor-capacitor voltage-controlled oscillator, including an inductor-capacitor core having a positive terminal and a negative terminal; a further inductor-capacitor core having a further positive terminal and a further negative terminal; and a switching circuit coupled to the positive terminal, the negative terminal, the further positive terminal, and the further negative terminal, where the switching circuit is controllable by one or more control signals to operate the switching circuit in one of multiple states.

Example 2 provides the reconfigurable multi-core inductor-capacitor voltage-controlled oscillator of example 1, where the multiple states include a straight-coupled state in which the positive terminal is electrically coupled to the further positive terminal, and the negative terminal is electrically coupled to the further negative terminal.

Example 3 provides the reconfigurable multi-core inductor-capacitor voltage-controlled oscillator of example 1 or 2, where the multiple states include a cross-coupled state in which the positive terminal is electrically coupled to the further negative terminal, and the negative terminal is electrically coupled to the further positive terminal.

Example 4 provides the reconfigurable multi-core inductor-capacitor voltage-controlled oscillator of any one of examples 1-3, where the multiple states include a decoupled state in which the positive terminal and the negative terminal are electrically isolated from the further positive terminal and the further negative terminal.

Example 5 provides the reconfigurable multi-core inductor-capacitor voltage-controlled oscillator of example 4, where the further inductor-capacitor core is inactive in the decoupled state.

Example 6 provides the reconfigurable multi-core inductor-capacitor voltage-controlled oscillator of any one of examples 1-5, further including a controller to output the one or more control signals based on a power mode of a communication system.

Example 7 provides the reconfigurable multi-core inductor-capacitor voltage-controlled oscillator of any one of examples 1-6, where the positive terminal and the negative terminal output a signal of a phase-locked loop.

Example 8 provides the reconfigurable multi-core inductor-capacitor voltage-controlled oscillator of any one of examples 1-7, where the switching circuit includes a plurality of transmission-gate switches.

Example 9 provides an integrated circuit for a communication system with improved tolerance to electromagnetic coupling, the integrated circuit including a communication lane including a signal processing path and a phase-locked loop coupled to the signal processing path, where the phase-locked loop includes a reconfigurable multi-core inductor-capacitor voltage-controlled oscillator operable to operate in a selected one of multiple modes; and a further communication lane including a further signal processing path and a further phase-locked loop, where the further phase-locked loop includes a further reconfigurable multi-core inductor-capacitor voltage-controlled oscillator operable to operate in a further selected one of the multiple modes.

Example 10 provides the integrated circuit of example 9, where the selected one of the multiple modes and the further selected one of the multiple modes are the same.

Example 11 provides the integrated circuit of example 9, where the selected one of the multiple modes and the further selected one of the multiple modes are different.

Example 12 provides the integrated circuit of any one of examples 9-11, where the reconfigurable multi-core inductor-capacitor voltage-controlled oscillator includes a plurality of inductor-capacitor cores; and a switching circuit coupled to the plurality of inductor-capacitor cores, where the switching circuit electrically configures one or more connections between the plurality of inductor-capacitor cores according to the selected one of the multiple modes.

Example 13 provides the integrated circuit of any one of examples 9-12, where the further reconfigurable multi-core inductor-capacitor voltage-controlled oscillator includes a plurality of further inductor-capacitor cores; and a further switching circuit coupled to the plurality of further inductor-capacitor cores, where the further switching circuit electrically configures one or more further connections between the plurality of further inductor-capacitor cores according to the further selected one of the multiple modes.

Example 14 provides the integrated circuit of any one of examples 9-13, further including a controller to select the selected one of the multiple modes and select the further selected one of the multiple modes.

Example 15 provides the integrated circuit of example 14, where the controller is to select the selected one of the multiple modes and select the further selected one of the multiple modes based on a power mode of the communication system.

Example 16 provides the integrated circuit of example 14 or 15, where the controller is to select the selected one of the multiple modes and select the further selected one of the multiple modes based on one or more of: a proximity of the communication lane to the further communication lane, a proximity of the communication lane to an electrical component of or near the integrated circuit, and a proximity of the further communication lane to a further electrical component of or near the integrated circuit.

Example 17 provides the integrated circuit of any one of examples 9-16, where the multiple modes include a low-power mode corresponding to inductor-capacitor cores being decoupled from each other in the reconfigurable multi-core inductor-capacitor voltage-controlled oscillator or the further reconfigurable multi-core inductor-capacitor voltage-controlled oscillator; a cross-coupled mode corresponding to the inductor-capacitor cores being cross-coupled with each other in the reconfigurable multi-core inductor-capacitor voltage-controlled oscillator or the further reconfigurable multi-core inductor-capacitor voltage-controlled oscillator; and a straight-coupled mode corresponding to the inductor-capacitor cores being straight-coupled with each other in the reconfigurable multi-core inductor-capacitor voltage-controlled oscillator or the further reconfigurable multi-core inductor-capacitor voltage-controlled oscillator.

Example 18 provides an integrated circuit for a communication system with improved tolerance to electromagnetic coupling, the integrated circuit including a plurality of phase-locked loops corresponding to a plurality of communication lanes, where each phase-locked loop includes a reconfigurable multi-core inductor-capacitor voltage-controlled oscillator having a plurality of inductor-capacitor cores, and a switching circuit coupled to terminals of the plurality of inductor-capacitor cores, the switching circuit being controllable to operate in one of multiple states; and a lane configuration register bank storing, for each of the plurality of phase-locked loops, a respective configuration value that selects a corresponding one of the multiple states, where at least two of the plurality of phase-locked loops are configured to operate their respective switching circuits in different states during operation of the plurality of communication lanes.

Example 19 provides the integrated circuit of example 18, where the respective configuration values stored in the lane configuration register bank are based on a power mode of the communication system.

Example 20 provides the integrated circuit of example 18 or 19, where the respective configuration values stored in the lane configuration register bank are based on one or more of: a proximity between two communication lanes, and a proximity of a communication lane of the plurality of communication lanes to an electrical component of or near the integrated circuit.

Example 21 provides the integrated circuit of any one of examples 18-20, where the multiple states include a low-power state corresponding to the plurality of inductor-capacitor cores being decoupled from each other; a cross-coupled state corresponding to the plurality of inductor-capacitor cores being cross-coupled with each other; and a straight-coupled state corresponding to the plurality of inductor-capacitor cores being straight-coupled with each other.

Example 22 provides a method of reducing electromagnetic coupling associated with an inductor-capacitor voltage-controlled oscillator on an integrated circuit, the method including applying one or more control signals to a switching circuit that interconnects terminals of a plurality of inductor-capacitor cores of a reconfigurable multi-core inductor-capacitor voltage-controlled oscillator according to a selected one of multiple states; and applying one or more further control signals to a further switching circuit that interconnects terminals of a plurality of further inductor-capacitor cores of a further reconfigurable multi-core inductor-capacitor voltage-controlled oscillator according to a further selected one of multiple states.

Example 23 provides the method of example 22, where the selected one of the multiple states and the further selected one of the multiple states are the same.

Example 24 provides the method of example 22, where the selected one of the multiple states and the further selected one of the multiple states are different.

Example 25 provides the method of example 22 or 23, further including generating the one or more control signals and the one or more further control signals based on a power mode of a communication system.

Example 26 provides the method of any one of examples 22-25, further including generating the one or more control signals and the one or more further control signals based on one or more of: a proximity between the reconfigurable multi-core inductor-capacitor voltage-controlled oscillator and the further reconfigurable multi-core inductor-capacitor voltage-controlled oscillator, a proximity of the reconfigurable multi-core inductor-capacitor voltage-controlled oscillator to an electrical component of or near the integrated circuit, and a proximity of the further reconfigurable multi-core inductor-capacitor voltage-controlled oscillator to a further electrical component of or near the integrated circuit.

Example 27 provides an apparatus with improved tolerance to electromagnetic coupling, the apparatus including means for generating an oscillation signal, where the means for generating the oscillation signal includes inductive-capacitive means; further inductive-capacitive means; and switching means for interconnecting the inductive-capacitive means and the further inductive-capacitive means; and means for controlling the switching means to operate the means for generating the oscillation signal in one of a plurality of states.

Example 28 provides the apparatus of example 27, where the switching means for interconnecting the inductive-capacitive means and the further inductive-capacitive means include means for straight-coupling the inductive-capacitive means and the further inductive-capacitive means; and means for cross-coupling the inductive-capacitive means and the further inductive-capacitive means.

Example 29 provides the apparatus of example 27, where the switching means for interconnecting the inductive-capacitive means and the further inductive-capacitive means include means for coupling the inductive-capacitive means and the further inductive-capacitive means; and means for decoupling the inductive-capacitive means and the further inductive-capacitive means.

Example 30 provides an apparatus comprising means for performing a method of any one of examples 22-26.

### Variations and Remarks

In some examples, the means for generating an oscillation signal corresponds to reconfigurable multi-core LC VCO 206 as illustrated in FIG. 4, comprising Core<0> 404 and Core<1> 406, each including inductor Ltank and capacitor bank CapBank, and switching circuit 402 interconnecting the terminals of Core<0> 404 and Core<1> 406 (as further illustrated in FIGS. 3A, 3B, 5A, and 5B), and equivalents thereof. The means for generating an oscillation signal further corresponds to VCO 206 as illustrated in FIG. 2 within PLL 140 or PLL 150, and to VCO 602 as illustrated in FIG. 6 within transceiver 104, and equivalents thereof.

In some examples, the inductive-capacitive means corresponds to an inductor-capacitor core, such as Core<0> 404, comprising inductor Ltank providing the inductive element of the LC tank resonator and capacitor bank CapBank providing the capacitive element of the LC tank resonator, powered by supply voltage Vreg_vco<0>, as illustrated in FIG. 4, and equivalents thereof.

In some examples, the further inductive-capacitive means corresponds to a further inductor-capacitor core, such as Core<1> 406, comprising inductor Ltank providing the inductive element of the LC tank resonator and capacitor bank CapBank providing the capacitive element of the LC tank resonator, powered by supply voltage Vreg_vco<1>, as illustrated in FIG. 4, and equivalents thereof.

In some examples, the switching means for interconnecting the inductive-capacitive means and the further inductive-capacitive means corresponds to switching circuit 402 as illustrated in FIGS. 4, 5A, and 5B, comprising one or more transmission-gate switches, each comprising a complementary PMOS transistor 510 and NMOS transistor 512 connected in parallel between input terminal IN and output terminal OUT and controlled by complementary control signals C and C as illustrated in FIG. 5C, disposed between the terminals of Core<0> 404 and Core<1> 406, and equivalents thereof.

In some examples, the means for controlling the switching means corresponds to controller 680 as illustrated in FIG. 6, configured to output one or more control signals to switching circuit 402 to select one of the plurality of states, optionally in conjunction with lane configuration register bank 682 storing configuration values for each communication lane, and equivalents thereof. The means for controlling the switching means further corresponds to the act of controlling the switching means as recited in step 804 of method 800 illustrated in FIG. 8, and equivalents thereof.

In some examples, the means for straight-coupling the inductive-capacitive means and the further inductive-capacitive means corresponds to the straight switches SS of switching circuit 402 as illustrated in FIG. 5B, which when closed electrically couple positive terminal P0 to further positive terminal P1 and negative terminal N0 to further negative terminal N1, causing both cores to oscillate in anti-phase and generating electromagnetic flux in opposing directions in each core for victim immunity, and equivalents thereof. The straight-coupling function is also performed by the straight interconnect embodiment of switching circuit 402 illustrated in FIG. 5A when all switches S are closed in a straight dual-core configuration.

In some examples, the means for cross-coupling the inductive-capacitive means and the further inductive-capacitive means corresponds to the criss-cross switches SX of switching circuit 402 as illustrated in FIG. 5B, which, when closed, electrically couple positive terminal P0 to further negative terminal N1 and negative terminal N0 to further positive terminal P1 through crossing interconnections, causing both cores to oscillate in-phase and generating electromagnetic flux in the same direction in each core for aggressor suppression, and equivalents thereof. The cross-coupling function is also performed by the criss-cross interconnect embodiment of switching circuit 402 illustrated in FIG. 5A when all switches S are closed in a criss-cross dual-core configuration.

In some examples, the means for coupling the inductive-capacitive means and the further inductive-capacitive means corresponds to switching circuit 402 as illustrated in FIGS. 4, 5A, and 5B, when one or more switches are closed to electrically interconnect terminals of Core<0> 404 and Core<1> 406 in either a straight-coupled or cross-coupled configuration corresponding to straight-coupled state 302 as illustrated in FIG. 3A, or a cross-coupled configuration, and equivalents thereof.

In some examples, the means for decoupling the inductive-capacitive means and the further inductive-capacitive means corresponds to switching circuit 402 as illustrated in FIGS. 4, 5A, and 5B, when all switches are open to electrically isolate Core<0> 404 from Core<1> 406, enabling single-core low-power operation, with one of Core<0> 404 or Core<1> 406 optionally powered down by disabling the respective supply voltage Vreg_vco<0> or Vreg_vco<1>, and equivalents thereof.

The detailed description, such as the “Select examples” section, provides various examples of the examples disclosed herein.

As used herein, the term “coupled to” or “coupled with” refers to a relationship between electronic components or circuit elements wherein the components are in electronic communication with one another and are capable of transmitting and/or receiving electrical signals between them. The term “coupled to” does not require a direct physical or electrical connection between the coupled components. Rather, “coupled to” can encompass arrangements where the components are connected through one or more intervening elements, components, circuits, or transmission paths. For example, a first component may be “coupled to” a second component through intermediate components such as resistors, capacitors, inductors, transistors, logic gates, buses, transformers, or other electronic components, or through intermediate transmission paths, while still maintaining the capability for electronic communication between the first and second components.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well-known features are omitted or simplified in order not to obscure the illustrative implementations.

Further, references are made to the accompanying drawings that form a part hereof, and in which are shown, by way of illustration, examples that may be practiced. It is to be understood that other examples may be utilized, and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order-dependent. In particular, these operations may not be performed in the order of presentation. Operations described may be performed in a different order from the described example. Various additional operations may be performed, or described operations may be omitted in additional examples.

For the purposes of the present disclosure, the phrase “A or B” or the phrase “A and/or B” means (A), (B), or (A and B). For the purposes of the present disclosure, the phrase “A, B, or C” or the phrase “A, B, and/or C” means (A), (B), (C), (A and B), (A and C), (B and C), or (A, B, and C). For the purposes of the present disclosure, the phrase “one or more of A, B, and C”, the phrase “at least one of A, B, and C”, or the phrase “at least one or more of A, B, and C” means (A), (B), (C), (A and B), (A and C), (B and C), or (A, B, and C). The term “between,” when used with reference to measurement ranges, is inclusive of the ends of the measurement ranges.

The description uses the phrases “in an example” or “in examples,” which may each refer to one or more of the same or different examples. The terms “comprising,” “including,” “having,” and the like, as used with respect to examples of the present disclosure, are synonymous. The disclosure may use perspective-based descriptions such as “above,” “below,” “top,” “bottom,” and “side” to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking, or in any other manner.

In the following detailed description, various aspects of the illustrative implementations will be described using terms commonly employed by those skilled in the art to convey the substance of their work to others skilled in the art.

The terms “substantially,” “close,” “approximately,” “near,” and “about,” generally refer to being within +/−20% of a target value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value as described herein or as known in the art.

In addition, the terms “comprise,” “comprising,” “include,” “including,” “have,” “having” or any other variation thereof, are intended to cover a non-exclusive inclusion. For example, a method, process, or device, that comprises a list of elements is not necessarily limited to only those elements but may include other elements not expressly listed or inherent to such method, process, or device. Also, the term “or” refers to an inclusive “or” and not to an exclusive “or.”

The systems, methods, and devices of this disclosure each have several innovative aspects, no single one of which is solely responsible for all desirable attributes disclosed herein. Details of one or more implementations of the subject matter described in this specification are set forth in the description and the accompanying drawings.

1. A reconfigurable multi-core inductor-capacitor voltage-controlled oscillator, comprising:
an inductor-capacitor core having a positive terminal and a negative terminal;
a further inductor-capacitor core having a further positive terminal and a further negative terminal; and
a switching circuit coupled to the positive terminal, the negative terminal, the further positive terminal, and the further negative terminal, wherein the switching circuit is controllable by one or more control signals to operate the switching circuit in one of multiple states.

2. The reconfigurable multi-core inductor-capacitor voltage-controlled oscillator of claim 1, wherein the multiple states comprise:
a straight-coupled state in which the positive terminal is electrically coupled to the further positive terminal, and the negative terminal is electrically coupled to the further negative terminal.

3. The reconfigurable multi-core inductor-capacitor voltage-controlled oscillator of claim 1, wherein the multiple states comprise:
a cross-coupled state in which the positive terminal is electrically coupled to the further negative terminal, and the negative terminal is electrically coupled to the further positive terminal.

4. The reconfigurable multi-core inductor-capacitor voltage-controlled oscillator of claim 1, wherein the multiple states comprise:
a decoupled state in which the positive terminal and the negative terminal are electrically isolated from the further positive terminal and the further negative terminal.

5. The reconfigurable multi-core inductor-capacitor voltage-controlled oscillator of claim 4, wherein the further inductor-capacitor core is inactive in the decoupled state.

6. The reconfigurable multi-core inductor-capacitor voltage-controlled oscillator of claim 1, further comprising:
a controller to output the one or more control signals based on a power mode of a communication system.

7. The reconfigurable multi-core inductor-capacitor voltage-controlled oscillator of claim 1, wherein the positive terminal and the negative terminal output a signal of a phase-locked loop.

8. The reconfigurable multi-core inductor-capacitor voltage-controlled oscillator of claim 1, wherein the switching circuit comprises a plurality of transmission-gate switches.

9. An integrated circuit for a communication system with improved tolerance to electromagnetic coupling, the integrated circuit comprising:
a communication lane comprising a signal processing path and a phase-locked loop coupled to the signal processing path, wherein the phase-locked loop comprises a reconfigurable multi-core inductor-capacitor voltage-controlled oscillator operable to operate in a selected one of multiple modes; and
a further communication lane comprising a further signal processing path and a further phase-locked loop, wherein the further phase-locked loop comprises a further reconfigurable multi-core inductor-capacitor voltage-controlled oscillator operable to operate in a further selected one of the multiple modes.

10. The integrated circuit of claim 9, wherein the selected one of the multiple modes and the further selected one of the multiple modes are the same.

11. The integrated circuit of claim 9, wherein the selected one of the multiple modes and the further selected one of the multiple modes are different.

12. The integrated circuit of claim 9, wherein the reconfigurable multi-core inductor-capacitor voltage-controlled oscillator comprises:
a plurality of inductor-capacitor cores; and
a switching circuit coupled to the plurality of inductor-capacitor cores, wherein the switching circuit electrically configures one or more connections between the plurality of inductor-capacitor cores according to the selected one of the multiple modes.

13. The integrated circuit of claim 9, wherein the further reconfigurable multi-core inductor-capacitor voltage-controlled oscillator comprises:
a plurality of further inductor-capacitor cores; and
a further switching circuit coupled to the plurality of further inductor-capacitor cores, wherein the further switching circuit electrically configures one or more further connections between the plurality of further inductor-capacitor cores according to the further selected one of the multiple modes.

14. The integrated circuit of claim 9, further comprising:
a controller to select the selected one of the multiple modes and select the further selected one of the multiple modes.

15. The integrated circuit of claim 14, wherein the controller is to select the selected one of the multiple modes and select the further selected one of the multiple modes based on a power mode of the communication system.

16. The integrated circuit of claim 14, wherein the controller is to select the selected one of the multiple modes and select the further selected one of the multiple modes based on one or more of: a proximity of the communication lane to the further communication lane, a proximity of the communication lane to an electrical component of or near the integrated circuit, and a proximity of the further communication lane to a further electrical component of or near the integrated circuit.

17. The integrated circuit of claim 9, wherein the multiple modes comprise:
a low-power mode corresponding to inductor-capacitor cores being decoupled from each other in the reconfigurable multi-core inductor-capacitor voltage-controlled oscillator or the further reconfigurable multi-core inductor-capacitor voltage-controlled oscillator;
a cross-coupled mode corresponding to the inductor-capacitor cores being cross-coupled with each other in the reconfigurable multi-core inductor-capacitor voltage-controlled oscillator or the further reconfigurable multi-core inductor-capacitor voltage-controlled oscillator; and
a straight-coupled mode corresponding to the inductor-capacitor cores being straight-coupled with each other in the reconfigurable multi-core inductor-capacitor voltage-controlled oscillator or the further reconfigurable multi-core inductor-capacitor voltage-controlled oscillator.

18. An integrated circuit for a communication system with improved tolerance to electromagnetic coupling, the integrated circuit comprising:
a plurality of phase-locked loops corresponding to a plurality of communication lanes, wherein each phase-locked loop includes a reconfigurable multi-core inductor-capacitor voltage-controlled oscillator having a plurality of inductor-capacitor cores, and a switching circuit coupled to terminals of the plurality of inductor-capacitor cores, the switching circuit being controllable to operate in one of multiple states; and
a lane configuration register bank storing, for each of the plurality of phase-locked loops, a respective configuration value that selects a corresponding one of the multiple states, wherein at least two of the plurality of phase-locked loops are configured to operate their respective switching circuits in different states during operation of the plurality of communication lanes.

19. The integrated circuit of claim 18, wherein the respective configuration values stored in the lane configuration register bank are based on a power mode of the communication system.

20. An apparatus with improved tolerance to electromagnetic coupling, the apparatus comprising:
means for generating an oscillation signal, wherein the means for generating the oscillation signal comprises:
inductive-capacitive means;
further inductive-capacitive means; and
switching means for interconnecting the inductive-capacitive means and the further inductive-capacitive means; and
means for controlling the switching means to operate the means for generating the oscillation signal in one of a plurality of states.
